(19) United States
(12) Patent Application Publication
(10) Pub. No.: US 2005/0073000 A1
(43) Pub. Date: Apr. 7, 2005

(54) Semiconductor memory device with less threshold variation

(76) Inventors: Kiyonori Oyu, Tokyo (JP); Atsushi Ogishima, Tokyo (JP)

Correspondence Address: HAYES, SOLOWAY P.C., 130 W. CUSHING STREET, TUCSON, AZ, 85701, US

(21) Appl. No.: 10/730,852

(22) Filed: Dec. 9, 2003

(30) Foreign Application Priority Data
Dec. 10, 2002 (JP) 357789/2002

(51) Int. Cl. H01L 29/76

(52) U.S. Cl. 257/314

(57) ABSTRACT

A semiconductor memory device includes a semiconductor substrate, and gate electrodes formed for a transistor on the semiconductor substrate through a gate insulating film. A gate length of the gate electrode is longer than a minimum processing dimension. The semiconductor memory device may further include a first diffusion layer formed in a surface of the semiconductor substrate to function as one of a source and a drain, and a second diffusion layer formed in the surface of the semiconductor substrate to function as the other of the source and the drain. The shortest distance between the first diffusion layer and the second diffusion layer is proportional to the gate length. In this case, the semiconductor memory device may further include a gate insulating film formed on the semiconductor substrate and extending over the first diffusion layer and the second diffusion layer. The gate electrode is formed on the gate insulating film.

### BACKGROUND OF THE INVENTION

1. Field of the Invention

The present invention relates to a semiconductor memory device, and more particularly relates to DRAM (Dynamic Random Access Memory).

2. Description of the Related Art

A DRAM as a kind of a semiconductor memory device is used as a main memory device of an apparatus such as a computer. In recent years, in the semiconductor memory device, a refreshing performance is improved as disclosed in Japanese Laid Open Patent Applications (JP-P2000-236074A; a first conventional example, and JP-P2000-174225A; a second conventional example) and a fine structure of the semiconductor memory device is achieved as disclosed in Japanese Laid Open Patent Applications (JP-A-Heisei 10-189899; a third conventional example, and JP-A-Heisei 4-112569; a fourth conventional example).

FIG. 1 is a plan view showing memory cell transistors of a conventional semiconductor memory device. Referring to FIG. 1, a capacitive contact section 104 and a capacitive contact section 104′ are connected on transistor regions 102 respectively. A cell capacitive section 106 is formed on the capacitive contact section 104, and a cell capacitive section 106′ is formed on the capacitive contact section 104′.

A bit line contact section 105 connected to a bit line is connected to the transistor region 102. A word line 101 and a word line 101′ as gate electrodes are separately laid on the transistor region 102. The word line 101 and the word line 101′ are extended vertically to the transistor region 102. The word line 101 is laid between the capacitive contact section 104 and the bit line contact section 105, and the word line 101′ is laid between the capacitive contact section 104′ and the bit line contact section 105. Hereafter, the word line 101 is also referred to as a gate electrode 101, and the word line 101′ is also referred to as a gate electrode 101′.

In the layout of the conventional memory cell transistor, a minimum processing dimension (half pitch) is represented by F. As shown in FIG. 1, the half pitch F is the shortest distance between the capacitive contact section 104′ connected to one transistor region 102 and the capacitive contact sections 104 connected to anther transistor region 102.

A gate interval indicative of an interval between the gate electrode 101 and the gate electrode 101′ is F. The capacitive contact sections 104 and 104′ for connecting the capacitive contact sections 104 and 104′ and the cell capacitive sections 106 and 106′ (contact sections 119 and 119′ connected to the cell capacitive sections 106 and 106′) are rectangular or circular (not shown) shape. The side of the rectangular contact or the diameter of a circular contact (not shown) is F. The bit line contact section 105 for connecting the bit line contact section 105 and a bit line (a bit line 120 as described later) is square or circular (not shown) shape. The side of the rectangular contact or the diameter of the circular contact is F.

The widths of the word lines 101 and 101′ or gate lengths are equal to or less than F.

FIG. 2 is a cross sectional view of the semiconductor memory device along the line B-B′ shown in FIG. 1.

Diffusion layers 111, 111′ and 112 are separately formed in the surface of a semiconductor substrate 110. The semiconductor substrate 110 is of a p-type, and the diffusion layers 111, 111′ and 112 are of an n-type. A shallow trench insulation film 113′ for device separation is formed in the surface of the semiconductor substrate 110. A shallow trench insulation film 113 for device separation is formed in the surface of the semiconductor substrate 110. The shallow trench insulation films 113 and 113′ for device separation are provided to electrically insulate the transistor regions 102 from each other. A gate oxide film 114 extends on the diffusion layer 111 and the diffusion layer 112 and a gate oxide film 114′ extends on the diffusion layer 111′ and the diffusion layer 112.

The gate electrode 101 is formed on the surface of the gate oxide film 114, and the gate electrode 101′ is formed on the surface of the gate oxide film 114′. The gate electrode 101 is formed on the surface of the shallow trench insulation film 113,. and the gate electrode 101′ is formed on the surface of the shallow trench insulation film 113′.

Nitride films 115 are formed on the surfaces of the gate electrodes 101 and 101. An interlayer insulating film 116 for covering the shallow groove element separating insulation films 113 and 113′ and the nitride films 115 is formed on the shallow groove element separating insulation films 113 and 113′ and the nitride films 115. The capacitive contact section 104 is formed to extend from the surface of the interlayer insulating film 116 to the diffusion layer 111. The capacitive contact section 104′ is formed extended from the surface of the interlayer insulating film 116 to the diffusion layer 111′. The bit line contact section 105 is formed to pass through the interlayer insulating film 116 to the diffusion layer 112.

Consequently, in the conventional memory cell transistor, a first MOS (Metal Oxide Semiconductor) transistor is formed on a first surface of the semiconductor substrate 110, and a second MOS transistor is formed on a second surface of the semiconductor substrate 110. That is, the first MOS transistor is constituted of the diffusion layer 111, the diffusion layer 112, the capacitive contact section 104, the bit line contact section 105, the gate insulating film 114 and the gate electrode 101. The second MOS transistor is constituted of the diffusion layer 111′, the capacitive contact section 104′, the diffusion layer 112, the bit line contact section 105, the gate insulating film 114 and the gate electrode 101′. The diffusion layer 112 and the bit line contact section 105 are used in common to the first and second MOS transistors in the conventional memory cell transistor.

The diffusion layer 111 of the first MOS transistor functions as one of a source and a drain, and the capacitive contact section 104 thereof functions as one of a source electrode and a drain electrode. The diffusion layer 112 of the first MOS transistor functions as the other of the source and the drain, and the bit line contact section 105 thereof functions as the other of the source electrode and the drain electrode. The diffusion layer 111′ of the second MOS transistor functions as one of a source and a drain, and the capacitive contact section 104′ thereof functions as one of a source electrode and a drain electrode. The diffusion layer 112 of the second MOS transistor functions as the other of the source and the drain, and the bit line contact section 105 thereof functions as the other one of the source electrode and the drain electrode.

An interlayer insulating film 117 is formed on the surface of the interlayer insulating film 116. The bit line 120 is formed on the surface of the bit line contact section 105 and extends on the surface of the interlayer insulating film 117.

An interlayer insulating film 118 is formed on the interlayer insulating film 117 and the bit line 120. A contact section 119 is formed to extend from the surface of the interlayer insulating film 118 to the capacitive contact section 104 and a contact section 119′ is formed to extend from the surface of the interlayer insulating film 118 to the capacitive contact section 104′. A cell capacitance lower electrode 121 is formed on the contact section 119 and the interlayer insulating film 118. The cell capacitance lower electrode 121 has a bottom surface 121-1 connected to the contact section 119 and the interlayer insulating film 118, and side walls 121-2 uprightly extending from the ends of the bottom surface 121-1. A cell capacitance lower electrode 121′ is formed on the contact section 119′ and the interlayer insulating film 118. The cell capacitance lower electrode 121′ has a bottom surface 121′-1 connected to the contact section 119′ and the interlayer insulating film 118 and side walls 121′-2 uprightly extending from the ends of the bottom surface 121′-1.

A capacitive insulating film 122 is formed to cover the surfaces of the cell capacitance lower electrodes 121 and 121′ and a part of the interlayer insulating film 118. A cell capacitance upper electrode 123 is formed to cover the capacitive insulating film 122. Consequently, a cell capacitive section 106 composed of the cell capacitance lower electrode 121, the capacitive insulating film 122 and the cell capacitance upper electrode 123 is formed on the capacitive contact section 104 through the contact section 119, and the cell capacitive section 106′ composed of the cell capacitance lower electrode 121′, the capacitive insulating film 122 and the cell capacitance upper electrode 123 is formed on the capacitive contact section 104′ through the contact section 119′.

The word line 101 is connected to a first word line terminal among a plurality of terminals. The word line 101′ is connected to a second word line terminal among the plurality of terminals. The bit line 120 is connected to a bit line terminal among the plurality of terminals. A reference terminal among the plurality of terminals is connected to the cell capacitance upper electrode 123.

A potential difference between the first word line terminal and the reference terminal is supplied to the word line 101. A potential difference between the second word line terminal and the reference terminal is supplied to the word line 101′. A potential difference between the bit line terminal and the reference terminal is supplied to the bit line 120.

As the operation of the conventional memory cell transistor, the case where data of “1” is written into a cell capacitance section will be described below. As the cell capacitance section, the cell capacitive section 106 is exemplified which is connected through the contact section 119 to the first MOS transistor.

The potential of the data “1” is supplied to the bit line 120. At this time, the potential of the diffusion layer 112 connected to the bit line contact section 105 becomes the data “1”. The potential of the data “1” is assumed to be a positive potential VDL. The potential of the diffusion layer 111 connected to the capacitive contact section 104 is set to VDL/2 immediately before the writing. At this time, if the potential is supplied to the gate electrode 101 to turn ON the first MOS transistor, the diffusion layer 112 connected to the bit line contact section 105 functions as the drain, and the diffusion layer 111 connected to the capacitive contact section 104 functions as the source. As a result, the data “1” is written to the cell capacitive section 106. That is, although the potential of the cell capacitance upper electrode 123 of the cell capacitive section 106 is VDL/2, the potential of the cell capacitance lower electrode 121 of the cell capacitive section 106 is VDL.

On the other hand, when the data “1” is read out from the cell capacitive section 106, the potential of the diffusion layer 112 connected to the bit line contact section 105 is set to VDL/2, and the potential of the diffusion layer 111 connected to the capacitive contact section 104 is set to VDL. For this reason, if the potential is supplied to the gate electrode 101 to turn ON the first MOS transistor, the diffusion layer 112 connected to the bit line contact section 105 functions as the source, and the diffusion layer 111 connected to the capacitive contact section 104 functions as the drain. As a result, the potential of the bit line 120 is varied, and the data “1” is read out by a sense amplifier (not shown) connected to the bit line 120.

After the data “1” is written to the cell capacitive section 106 (the cell capacitive section 106′) as mentioned above, the potential is supplied to the gate electrode 101 (the gate electrode 101′) to turn OFF the first MOS transistor (the second MOS transistor). The state in which the cell capacitive section 106 (the cell capacitive section 106′) holds the data “1” is referred to as a data holding state. Also, the time until the data “1” is broken after the data “1” is written to the cell capacitive section 106 (the cell capacitive section 106′), namely, the time while the cell capacitive section 106 (the cell capacitive section 106′) can hold the data “1” is referred to as an data holding time.

PN junctions are formed between the n-type diffusion layers 111, 111′ and 112 and the p-type semiconductor substrate 110. After the data “1” is written to the cell capacitive sections 106 and 106′, the potentials of the n-type diffusion layers 111, 111′ and 112 with respect to the p-type semiconductor substrate 110 are VDL, and a reverse voltage is applied to the PN junction. In the ideal case that leak current (junction leak current) does not flow through the junctions between the diffusion layers 111, 111′ and 112 and the semiconductor substrate 110, the data “1” accumulated in the cell capacitive sections 106 and 106′ are not broken.

However, the junction leak current usually flow through the junctions between the semiconductor substrate 110 and the diffusion layers 111, 111′ and 112. Thus, the potentials in the cell capacitance lower electrodes 121 and 121′ of the cell capacitive sections 106 and 106′ are gradually reduced from VDL. If the potential is reduced to VDL/2, the data “1” is perfectly broken. The changes in the potentials of those cell capacitance lower electrodes 121 and 121′ are determined based on the junction leak current. When the junction leak current is larger, the potentials of the cell capacitance lower electrodes 121 and 121′ are reduced faster. In this way, the data holding time depends on this junction leak current. Therefore, as the junction leak current becomes greater, the data holding time is made shorter. In such a case, the data holding performance is not good.

On the other hand, as this junction leak current is smaller, the data holding time can be made longer, thereby improving the data holding performance. In order to reduce this junction leak current, it is required to reduce the electric field (the electric field of the junction) in the junctions between the diffusion layers 111, 111′ and 112 and the semiconductor substrate 110.

In recent years, DRAM (Dynamic Random Access Memory) as a kind of the semiconductor memory device is used in a portable apparatus including a portable telephone and is requested to reduce power consumption. The power consumption is determined based on a refresh operation. That is, the power consumption is determined based on the powers used in charging and discharging operations when the data is written into the DRAM and when the data is read out from the DRAM. If the data holding time can be made longer, it is possible to reduce the power used in the charging and discharging operations.

However, the gate lengths of the gate electrodes 101 and 101′ are equal to or less than F. If the miniaturization is advanced under the structure shown in FIG. 1, the following problems would be caused.

At first, if the miniaturization is advanced under the assumption that the gate length of the memory cell transistor is F, a concentration of impurities in the semiconductor substrate 110 needs to be higher than the conventional memory cell transistor, in order to protect decrease in a threshold voltage Vth of the memory cell transistor. In this case, the electric fields on the interfaces between the diffusion layers 111, 111′ and 112 and the semiconductor substrate 110 become greater than the conventional memory cell transistor. Consequently, the data holding time becomes shorter than the conventional memory cell transistor.

Secondly, the dimensional variation when the gate electrodes 101 and 101′ are processed results in a main factor of the variation in the threshold voltage Vth, which brings about a disturb defect. In order to avoid this defect, the concentration of the semiconductor substrate 110 needs to be higher than the conventional memory cell transistor. However, if the concentration of the semiconductor substrate 110 is made higher than the conventional memory cell transistor, the variation in the threshold voltage Vth is further increased. Also, if the concentration of the semiconductor substrate 110 is made higher, the variation in the threshold voltage Vth is made greater. As a result, bits not written sufficiently would increase and bring about the write defect. In this way, it is difficult to solve the disturb defect and the write defect at the same time, which consequently disables the device operation.

Such reason will be described below.

In a case of 256-Mbit DRAM, the threshold voltage Vth and its variation shown in FIG. 3 are required for the memory cell transistor. A horizontal axis X in FIG. 3 indicates an average of the threshold voltages Vth in the memory cell transistor and a vertical axis in FIG. 3 indicates a variation σ in the threshold voltage Vth of the memory cell transistor. The variation σ is caused by the processing variations in the gate electrodes 101 and 101′, a dopant impurity concentration distribution and a gate oxide film thickness. FIG. 3 shows threshold lines S1 and S2 that the data destruction is induced through channel leak at a high temperature (about 85° C.), in the transistor of the minimum threshold voltage Vth in the 256 M bits, when a sub threshold coefficient S is given.

The threshold line S1 is the threshold line when the sub threshold coefficient S is 80 mV/dec, and is represented by a function Y1=a*X+b1 (a and b1 are constants). The plane coordinate indicated by the horizontal axis X and the vertical axis Y is partitioned off into a first region equal to or greater than the function value Y1 represented by the threshold line S1 and a second region less than the function value Y1 represented by the threshold line S1. The threshold line S2 is the threshold line when the sub threshold coefficient S is 90 mV/dec, and it is represented by a function Y2=a*X+b2 (a and b2 are constants). The plane coordinate indicated by the horizontal axis X and the vertical axis Y is partitioned off into a first region equal to or greater than the function value Y2 represented by the threshold line S2 and a second region less than the function value Y2 represented by the threshold line S2, by the threshold line S2.

In the case of the second region partitioned off by the threshold lines S1 and S2, the data destruction is not induced by the channel leak. In the case of the first region partitioned off by the threshold lines S1 and S2, the data destruction is induced by the channel leak.

Also, FIG. 3 shows threshold lines W1, W2 and W3 where a write defect is induced in the transistor of the maximum threshold voltage Vth in the 256 Mbits, when a write rate indicative of a rate of a writing operation guarantee of required data is given.

The threshold line W1 is the threshold line for the writing operation guarantee of 60%, and it is represented by a function Y11=−c*X+d11 (c and d11 are constants). The plane coordinate indicated by the horizontal axis X and the vertical axis Y is partitioned off into a first region equal to or greater than the function value Y11 represented by the threshold line W1 and a second region less than the function value Y11 represented by the threshold line W1. Also, the threshold line W2 is the threshold line for the writing operation guarantee of 70%, and it is represented by a function Y12=−c*X+d12 (c and d12 are constants). The plane coordinate indicated by the horizontal axis X and the vertical axis Y is partitioned off into a first region equal to or greater than the function value Y12 represented by the threshold line W2 and a second region less than the function value Y12 represented by the threshold line W2. Also, the threshold line W3 is the threshold line for the writing operation guarantee of 80%, and it is represented by a function Y13=−c*X+d13 (c and d13 are constants). The plane coordinate indicated by the horizontal axis X and the vertical axis Y is partitioned off into a first region equal to or greater than the function value Y13 represented by the threshold line W3 and a second region less than the function value Y13 represented by the threshold line W3.

In the case of the second region partitioned off by the threshold lines W1, W2 and W3, the write defect is not induced. In the case of the first region partitioned off by the threshold lines W1, W2 and W3, the write defect is induced.

The problems of the conventional memory cell transistor will be described below in detail with reference to FIG. 3.

When the gate length F of the memory cell transistor is assumed to be 0.13 μm, it is supposed that the average of the threshold voltages Vth is 1 V as indicated by a white circular mark in FIG. 3. In this case, the sub threshold coefficient S is 90 mV/dec, and the variation σ in the threshold voltages Vth is 90 mV. In this case, since the variation σ is located in is the first region partitioned off by the threshold line S2, the data destruction would be caused by the channel leak. Moreover, even if the write rate is reduced to 60%, the write defect is induced because of the first region partitioned off by the threshold line W1. That is, since the solution can not be obtained in this process, the reduction in the variation in the threshold voltages Vth is needed. Specifically, in order to guarantee the writing rate of 75% and protect the data destruction caused by the channel leak, the variation σ in the threshold voltages Vth needs to be 70 mV or less.

The factor analysis of the variation in the threshold voltages Vth is performed. It is supposed that the dimensional variation (the processing variation) when the gate electrodes 101 and 101′ are processed is 4 nm, the variation a in the threshold voltages Vth caused by the processing variations of the gate electrodes 101 and 101′ is 50 mV. With respect to the variation σ in the threshold voltages Vth, the remaining 40 mV in the entire 90 mV is caused by the variation in the threshold voltages Vth, which results from the dopant impurity concentration distribution and the gate oxide film thickness.

In order to reduce the variation in the threshold voltages Vth, the concentration of the semiconductor substrate 110 must be made higher. When the concentration of the semiconductor substrate 110 is made higher, the junction electric field in the interfaces between the diffusion layers 111, 111′ and 112 and the semiconductor substrate 110 is made higher, thereby increasing the junction leak current flowing through the interfaces between the diffusion layers 111, 111′ and 112 and the semiconductor substrate 110. If this junction leak current is increased, the data holding time of the memory cell transistor is made shorter. Thus, the data holding performance is made poor and the data holding performance is not improved.

In the conventional memory cell transistor, the advancement of the hyperfine structure disables the data holding performance to be improved and further disables the device operation to be executed.

Also, in the conventional memory cell transistor, since the data holding time is short, the electric power consumptions in the charging and discharging operations when the data are written to the cell capacitive sections 106 and 106′ and when the data are read out from the cell capacitive sections 106 and 106′.

### SUMMARY OF THE INVENTION

Therefore, an object of the present invention is to provide a semiconductor memory device in which a data holding time can be made longer.

Another object of the present invention is to provide a semiconductor memory device in which power consumption is reduced.

Still another object of the present invention is to provide a semiconductor memory device which is operated at a high speed.

In an aspect of the present invention, a semiconductor memory device includes a semiconductor substrate, and gate electrodes formed for a transistor on the semiconductor substrate through a gate insulating film. A gate length of the gate electrode is longer than a minimum processing dimension.

Here, the semiconductor memory device may further include a first diffusion layer formed in a surface of the semiconductor substrate to function as one of a source and a drain, and a second diffusion layer formed in the surface of the semiconductor substrate to function as the other of the source and the drain. The shortest distance between the first diffusion layer and the second diffusion layer is proportional to the gate length. In this case, the semiconductor memory device may further include a gate insulating film formed on the semiconductor substrate and extending over the first diffusion layer and the second diffusion layer. The gate electrode is formed on the gate insulating film.

Also, the semiconductor memory device may further include a first insulating film provided to cover the gate electrode, a first contact section formed to pass through the first insulating film to the first diffusion layer, a bit line formed on the insulating film, a second contact section formed to pass through the insulating film to the second diffusion layer, and a capacitive section formed on the first insulating film and connected to the first contact section. In this case, it is desirable that a side length or diameter of the first contact section is the minimum processing dimension, and a side length or diameter the second contact section t is the minimum processing dimension. Also, the semiconductor memory device may further include a second insulating film formed to cover the first insulating film, the first contact section, the second contact section and the bit line. The capacitive section is formed on the second insulating film, and the capacitive section may include a lower electrode, a capacitive insulating film formed on the lower electrode and an upper electrode formed on the capacitive insulating film. The semiconductor memory device may further include a third contact section formed to pass through the second insulating film to the first contact section.

Also, an impurity concentration of the semiconductor substrate is desirably lower than an impurity concentration of the semiconductor substrate when the gate length of the gate electrode is the minimum processing dimension.

Also, the gate length of the gate electrode is desirably equal to or longer than 1.3 times the minimum processing dimension.

In another aspect of the present invention, a semiconductor memory device includes a first MOS transistor formed on a first surface of a semiconductor substrate, and a second MOS transistor formed on a second surface of the semiconductor substrate. The first MOS transistor has a first gate electrode, the second MOS transistor has a second gate electrode, and a gate length of the first gate electrode and a gate length of the second gate electrode are longer than a minimum processing dimension. In this case, the first MOS transistor may further include a first diffusion layer functioning as one of a source and a drain and a second diffusion layer functioning as the other of the source and the drain, and the second MOS transistor may further include a third diffusion layer functioning as one of the source and the drain and the second diffusion layer functioning as the other of the source and the drain. The second diffusion layer is used in common to the first MOS transistor and the second MOS transistor. The shortest distance between the first diffusion layer and the second diffusion layer is proportional to the gate length of the first gate electrode, and the shortest distance between the third diffusion layer and the second diffusion layer is proportional to the gate length of the second gate electrode.

In this case, the first MOS transistor may further include a first gate insulating film extending over the first diffusion layer and the second diffusion layer, and the second MOS transistor may further include a second gate insulating film extending over the third diffusion layer and the second diffusion layer. Also, the first gate electrode is formed on the first gate insulating film, and the second gate electrode is formed on the first gate insulating film.

Also, the semiconductor memory device may further include a first insulating film formed to cover the first gate electrode and the second gate electrode, a first contact section formed to pass through the first insulating film to the first diffusion layer, and a second contact section formed to pass through the first insulating film to the second diffusion layer. Also, the semiconductor memory device may further include a bit line formed on the first insulating film, a third contact section formed to pass through the first insulating film to the third diffusion layer, a first capacitive section formed on the first insulating film and connected to the first contact section, and a second capacitive section formed on the first insulating film and connected to the third contact section. In this case, a side length or diameter of the first contact section is the minimum processing dimension, a side length or diameter of the second contact section is the minimum processing dimension, and a side length or diameter of the third contact section is the minimum processing dimension.

In this case, the semiconductor memory device may further include a second insulating film formed to cover the first insulating film, the first contact section, the second contact section, the third contact section and the bit line. The first capacitive section and the second capacitive section are formed on the second insulating film, and each of the first capacitive section and the second capacitive section has a lower electrode, a capacitive insulating film formed on the lower electrode and an upper electrode formed on the capacitive insulating film. The semiconductor memory device may further include a fourth contact section formed to pass through the second insulating film to the first contact section, and a fifth contact section formed to pass through the second insulating film to the third contact section.

Also, a gate interval between the first gate electrode and the second gate electrode is the minimum processing dimension.

Also, an impurity concentration of the semiconductor substrate is lower than an impurity concentration of the semiconductor substrate when the gate length of the first gate electrode and the gate length of the second gate electrode are the minimum processing dimension.

Also, the gate length of the first gate electrode and the gate length of the second gate electrode are equal to or longer than 1.3 times the minimum processing dimension.

### BRIEF DESCRIPTION OF THE DRAWINGS

FIG. 1 is a plan view showing memory cells of a conventional semiconductor memory device;

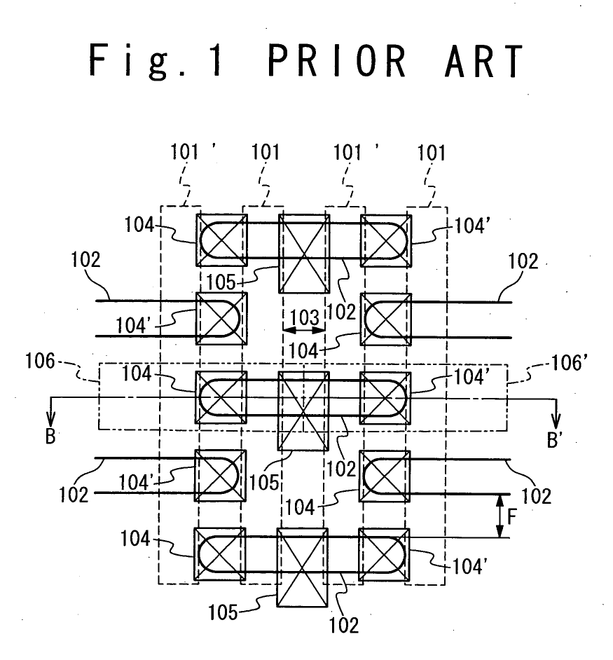

FIG. 2 is a sectional view of the memory cells along the line B-B′ of FIG. 1;

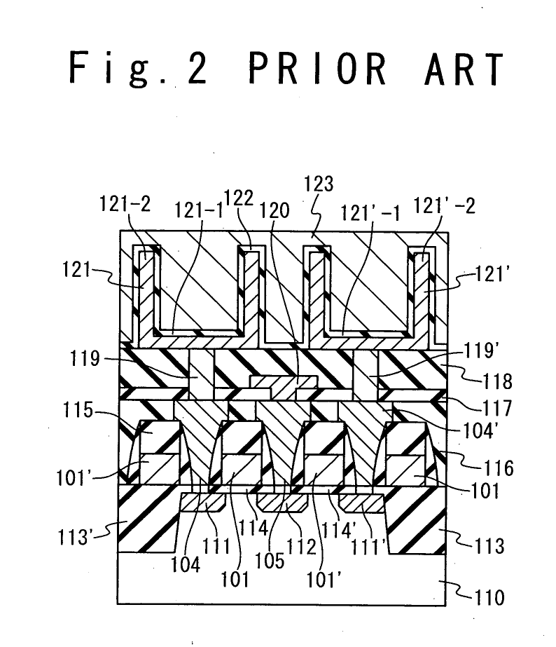

FIG. 3 is a graph showing

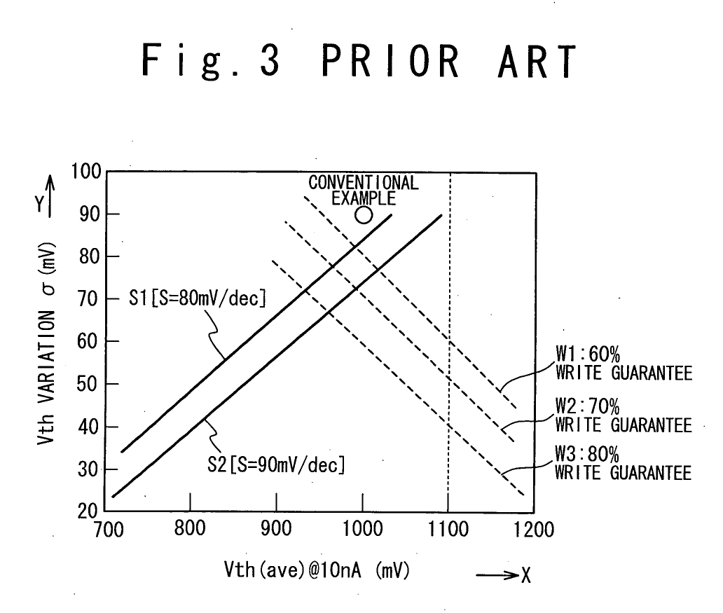

FIG. 4 is a plan view showing memory cells in a semiconductor memory device according to a first embodiment of the present invention;

FIG. 5 is a sectional view of the memory cells along the line A-A′ of FIG. 4;

FIG. 6 is a graph showing a relation between a gate length of a memory cell transistor and a threshold voltages Vth of the memory cell transistor;

FIG. 7 is a graph showing a relation between a relative substrate concentration and a variation in the threshold voltage Vth of the memory cell transistor;

FIG. 8 is a graph showing a relation between an average of the threshold voltages Vth and a variation in the threshold voltage Vth; and

FIG. 9 shows a relation between a normalized gate length and a normalized data holding time.

### DESCRIPTION OF THE PREFERRED EMBODIMENTS

Hereinafter, a semiconductor memory device such as a DRAM according to the present invention will be described below with reference to the attached drawings.

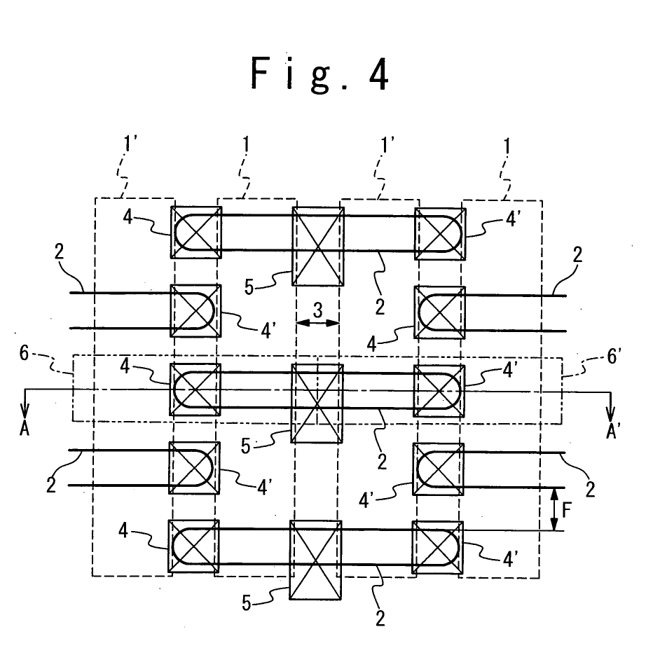

FIG. 4 is a plan view showing memory cell transistors of the semiconductor memory device according to the first embodiment of the present invention.

Capacitive contact sections 4 and capacitive contact sections 4′ are separately provided to connect it to each of a plurality of transistor regions. A cell capacitive section 6 is formed on the capacitive contact section 4, and a cell capacitive section 6′ is formed on the capacitive contact section 4′. A bit line contact section 5 is connected to a bit line and each of the transistor regions 2.

A word line 1 and a word line 1′ as gate electrodes are separately laid on each of the transistor regions 2. The word line 1 and 1′ are extended in a direction perpendicular to the transistor region 2. The word line 1 is laid between the capacitive contact section 4 and the bit line contact section 5, and the word line 1′ is laid between the capacitive contact section 4′ and the bit line contact section 5.

In the layout of the memory cell transistor according to the present invention, a minimum processing dimension (half pitch) is represented by F. For example, as shown in FIG. 4, the half pitch F is the shortest distance between two of the transistor regions 2 adjacent to each other in the perpendicular direction. A gate interval between the gate electrode 1 and the gate electrode 1′ is F, too. Each of the capacitive contact sections 4 and 4′ has a rectangular or circular shape. The side of the rectangle or the diameter of the circle is F. The bit line contact section 5 has a rectangular or circular shape and the side of the rectangle or the diameter of the circle is F. The width of each of the word lines 1 and 1′, which is proportional to a gate length is longer than the half pitch F and equal to or longer than 1.3 times the half pitch F. This value is equal to or longer than 1.3 times the gate length F of the gate electrodes 101 and 101′ in the conventional memory cell transistor.

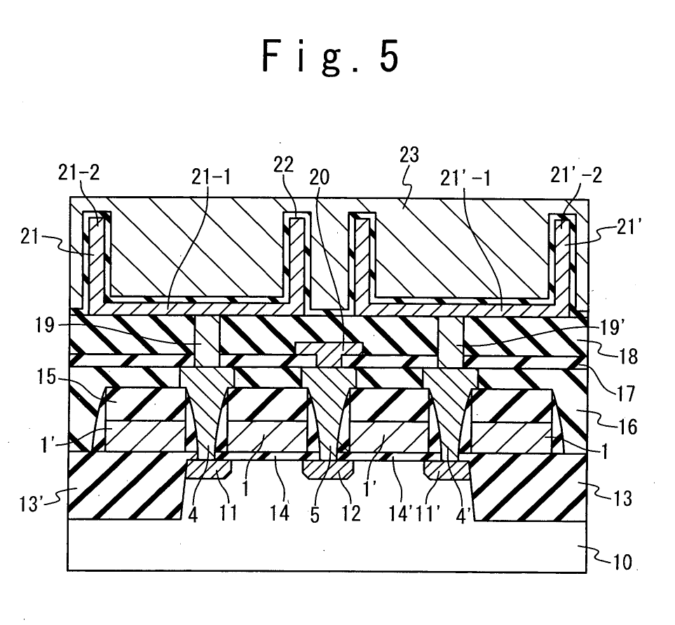

FIG. 5 is a cross sectional view of the transistor region along the line A-A′ of FIG. 4. Referring to FIG. 5, a diffusion layer 11, a diffusion layer 11′ and a diffusion layer 12 are separately formed in the surface of a semiconductor substrate 10. The semiconductor substrate 10 is of a p-type, and the diffusion layers 11, 11′ and 12 are of an n-type. The semiconductor substrate 10 and the diffusion layers 11, 11′ and 12 constitute the transistor region 2.

A shallow trench insulation film 13′ for device separation is formed in the surface of the semiconductor substrate 10 outside the diffusion layer 11. A shallow trench insulation film 13 for device separation is formed in the surface of the semiconductor substrate 10 outside the diffusion layer 11′. The shallow trench insulation film 13 and 13′ electrically isolates the transistor regions 2 from each other. A gate oxide film 14 and a gate oxide film 14′ extend over the diffusion layer 11, the diffusion layer 11′, the diffusion layer 12 and the surface of the semiconductor substrate 10. A gate electrode 1 is formed on the surface of the gate oxide film 14, and a gate electrode 1′ is formed on the surface of the gate oxide film 14′. The gate electrode 1 is also formed on the surface of the shallow trench isolation film 13, and the gate electrode 1′ is formed on the surface of the shallow trench isolation film 13′.

The shortest distance between the diffusion layer 11 and the diffusion layer 12 depends on the gate length of the gate electrode 1 and is equal to or longer than 1.3 times the shortest distance between the diffusion layer 111 and the diffusion layer 112 in the conventional memory cell transistor. The shortest distance between the diffusion layer 11′ and the diffusion layer 12 depends on the gate length of the gate electrode 1′ and is equal to or longer than 1.3 times the shortest distance between the diffusion layer 111′ and the diffusion layer 112 in the conventional memory cell transistor.

Nitride films 15 are formed on the gate electrodes 1 and 1′. Side wall insulating films are formed to surround each of the gate electrodes. An interlayer insulating film 16 is formed to cover the semiconductor substrate the nitride films 15 and the side wall insulating films.

The capacitive contact section 4 is formed to pass through the interlayer insulating film 16 to the diffusion layer 11. The capacitive contact section 4′ is formed to pass through the interlayer insulating film 16 to the diffusion layer 11′. The bit line contact section 5 is formed to pass through the interlayer insulating film 16 to the diffusion layer 12. Consequently, in the memory cell transistor of the present invention, a first MOS transistor is formed on a first surface of the semiconductor substrate 10, and a second MOS transistor is formed on a second surface of the semiconductor substrate 10. The diffusion layer 12 and the bit line contact section 5 are used in common to the first and second MOS transistors in the memory cell transistor of the present invention.

The diffusion layer 11 of the first MOS transistor and the diffusion layer 11′ of the second MOS transistor function as one of sources and drains, and the capacitive contact section 4 thereof functions as one of a source electrode and a drain electrode. The diffusion layer 12 functions as the other of the source and the drain, and the bit line contact section 5 thereof functions as the other of the source electrode and the drain electrode.

An interlayer insulating film 17 is formed to cover the interlayer insulating film 16, the capacitive contact sections 4 and 4′ and the bit line contact section 5. An interlayer insulating film 18 is formed on the interlayer insulating film 17. A bit line 20 is formed to pass through the interlayer insulating films 17 and 18 to the bit line contact section 5. The contact sections 19 and 19′ are formed to pass through the interlayer insulating films 17 and 18 to the capacitive contact sections 4 and 4′, respectively.

Cell capacitance lower electrodes 21 and 21′ are formed on the interlayer insulating film 18 to be connected with the contact sections 19 and 19′, respectively. The cell capacitance lower electrode 21 has a bottom portion 21-1 connected to the contact section 19, side wall portions 21-2 extending upwardly from the ends of the bottom portion 21-1. The cell capacitance lower electrode 21′ has a bottom portion 21′-1 connected to the contact section 19′, and side wall portions 21′-2 extending upwardly from the ends of the bottom portion 21′-1. A capacitive insulating film 22 is formed to cover the cell capacitance lower electrodes 21 and 21′ and the interlayer insulating film 18. A cell capacitance upper electrode 23 is formed on the capacitive insulating film 22.

Consequently, the cell capacitive section 6 is formed on the capacitive contact section 4 to have the cell capacitance lower electrode 21, the capacitive insulating film 22 and the cell capacitance upper electrode 23, and the cell capacitive section 6′ formed on the capacitive contact section 4′ to have the cell capacitance lower electrode 21′, the capacitive insulating film 22 and the cell capacitance upper electrode 23.

The word line 1 is connected to a first one of a plurality of terminals. The word line 1′ is connected to a second one of the plurality of terminals. The bit line 20 is connected to one of the plurality of terminals. A reference terminal of the plurality of terminals is connected to the cell capacitance upper electrode 23.

A potential difference is applied between the first word line terminal and the reference terminal, and a potential difference is applied between the second word line terminal and the reference terminal. A potential difference is applied between the bit line terminal and the reference terminal.

In the operation of the memory cell transistor of the present invention, a case when the data “1”. is written into the cell capacitance section will be described below. As the cell capacitance section, the cell capacitive section 6 connected through the contact section 19 to the first MOS transistor is exemplified.

The potential of the data “1” is supplied from an external apparatus (not shown) to the bit line 20. At this time, the potential of the diffusion layer 12 connected to the bit line contact section 5 becomes the data “1”. The potential of the data “1” is assumed to be the positive potential VDL. The potential of the diffusion layer 11 connected to the capacitive contact section 4 is set to VDL/2 immediately before the writing operation. For this reason, if the potential to turn ON the first MOS transistor is supplied from the external apparatus (not shown) to the gate electrode 1, the diffusion layer 12 connected to the bit line contact section 5 functions as the drain, and the diffusion layer 11 connected to the capacitive contact section 4 functions as the source. As a result, the data “1” is written to the cell capacitive section 6. That is, although the potential of the cell capacitance upper electrode 23 of the cell capacitive section 6 is VDL/2, the potential of the cell capacitance lower electrode 21 of the cell capacitive section 6 is VDL.

On the other hand, if the data “1” is read out from the cell capacitive section 6, the potential of the diffusion layer 12 connected to the bit line contact section 5 is VDL/2, and the potential of the diffusion layer 11 connected to the capacitive contact section 4 is VDL. For this reason, if the potential to turn ON the first MOS transistor is supplied from the external apparatus (not shown) to the gate electrode 1, the diffusion layer 12 connected to the bit line contact section 5 functions as the source, and the diffusion layer 11 connected to the capacitive contact section 4 functions as the drain. As a result, the potential of the bit line 20 is varied, and the data “1” is amplified by a sense amplifier (not shown) and read out by the external apparatus connected to the bit line 20.

After the data “1” is written to the cell capacitive section 6 as mentioned above, when the potential to turn OFF the first MOS transistor is supplied from the external apparatus (not shown) to the gate electrode 1, the state that the cell capacitive section 6 holds the data “1” is referred to as a data holding state. Also, the time until the data “1” is broken after the data “1” is written to the cell capacitive section 6, namely, the time while the cell capacitive section 6 holds the data “1” is referred to as the data holding time.

The PN junctions are formed between the n-type diffusion layers 11, 11′ and 12 and the p-type semiconductor substrate 10. After the data “1” is written into the cell capacitive sections 6, the potentials of the n-type diffusion layers 11, 11′ and 12 with respect to the p-type semiconductor substrate 10 are VDL. As a result, the reverse voltage is applied to the PN junction portion. In an ideal case that the leak current does not flow into the interfaces between the diffusion layers 11, 11′ and 12 and the semiconductor substrate 10, the data “1” accumulated in the cell capacitive sections 6 are not broken.

However, since the junction leak currents usually flow into the interfaces between the semiconductor substrate 10 and the diffusion layers 11, 11′ and 12, the data “1” as charge in the cell capacitive sections 6 is gradually reduced. The potential of the cell capacitance lower electrode 21 in the cell capacitive section 6 is gradually reduced from VDL. If the potential is reduced to VDL/2, the data “1” is perfectly broken. The change in the potential of the cell capacitance lower electrode 21 is determined based on this junction leak current. When this junction leak current is larger, the potential of the cell capacitance lower electrode 21 is reduced faster. In this way, the data holding time depends on this junction leak current. Thus, as the junction leak current becomes greater, the data holding time is made shorter. In such a case, the data holding performance is said to be bad.

On the other hand, as this junction leak current is smaller, the data holding time can be made longer, thereby improving the data holding performance. In order to reduce this junction leak current, it is required to reduce the electric field in the interfaces between the diffusion layers 11, 11′ and 12 and the semiconductor substrate 10.

(First Example)

In the layout of the memory cell transistor in the first example, the gate lengths of the gate electrodes 1 and 1′ are 1.3 times the half pitch F, namely, 1.3 F that is 1.3 times the gate lengths F of the gate electrodes 101 and 101′ in the conventional memory cell transistor. The half pitch F is the minimum processing dimension shown in FIG. 4 and is assumed to be 0.13 μm. When resist dimensions before the gate electrodes 1 and 1′ are processed are assumed to be 0.145 μm, the contraction is carried out through the side etching when the gate electrodes 1 and 1′ are processed. After the gate electrodes 1 and 1′ are processed, thermal oxidization is performed on the side walls of the gate electrodes 1 and 1′. As a result, the effective gate lengths of the gate electrodes 1 and 1′ in this first example are 0.17 μm.

In another layout of the memory cell transistor in the first embodiment, the following is carried out.

At first, the gate interval between the gate electrode 1 and the gate electrode 1′ is defined as F in order to protect the area from being unnecessarily increased. The sides or diameters of the capacitive contact sections 4 and 4′ are also defined as F in order to protect the area from being unnecessarily increased. The side or diameter of the bit line contact section 5 is also defined as F in order to protect the area from being unnecessarily increased.

As for the transistor region 2, the gate lengths of the gate electrodes 1 and 1′ are 1.3 times longer, compared with the gate lengths of the gate electrodes 101 and 101′ in the conventional memory cell transistor. That is, the shortest distance between the diffusion layer 11 and the diffusion layer 12 is proportional to the gate length of the gate electrode 1 and 1.3 times longer than the shortest distance between the diffusion layer 111 and the diffusion layer 112 in the conventional memory cell transistor. The shortest distance between the diffusion layer 11′ and the diffusion layer 12 is also proportional to the gate length of the gate electrode 1′ and 1.3 times longer than the shortest distance between the diffusion layer 111′ and the diffusion layer 112 in the conventional memory cell transistor.

In this way, in the memory cell transistor in the first example, the area per cell is increased. In accordance with this increase in the area, in the memory cell transistor in the first example, the areas of the cell capacitive sections 6 and 6′ can be increased over those of the cell capacitive sections 106 and 106′ of the conventional memory cell transistor.

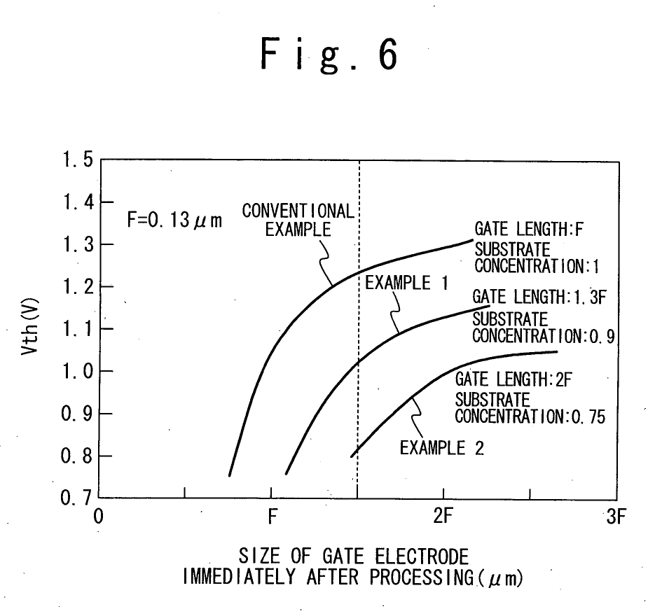

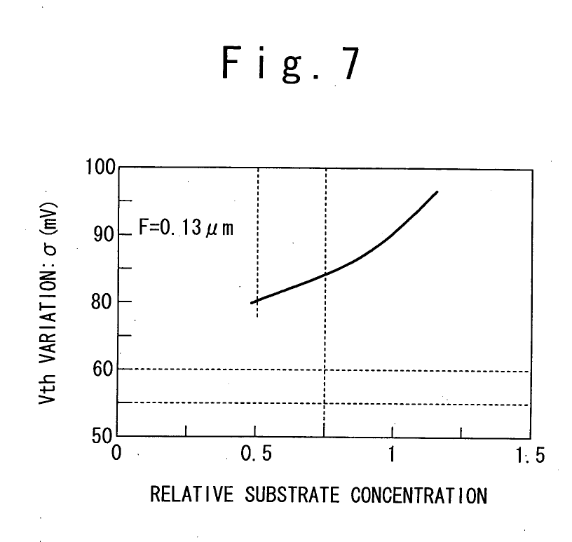

The memory cell transistor in the first example will be described below in detail with reference to FIGS. 6 and 7.

FIG. 6 shows a relation between the gate lengths of the gate electrodes of the memory cell transistors in the conventional example and the present invention and the threshold voltages Vth of the memory cell transistors in the conventional example and the present invention. Here, in the conventional memory cell transistor, a concentration of impurities doped into the semiconductor substrate 110 is assumed to be 1 when the gate electrodes 101 and 101′ whose gate lengths are F are used to adjust the threshold voltage Vth to 1 V. In the memory cell transistor of the first example, the concentration of the impurities doped into the semiconductor substrate 10 is 0.9 when the gate electrodes 1 and 1′ whose gate lengths are 1.3 F are used to adjust the threshold voltage Vth to 1 V. That is, the concentration of the semiconductor substrate 10 is 10% lower than the concentration of the semiconductor substrate 110. For this reason, it is supposed that the dimensional variation in the processing when the gate electrodes 1 and 1′ in the first example are processed is 4 nm equal to the processing variation of the conventional gate electrodes 101 and 101′. In this case, the variation σ in the threshold voltages Vth caused by the processing variation of the conventional gate electrodes 101 and 101′ is 50 mV. However, the variation σ in the threshold voltages Vth caused by the processing variation of the gate electrodes 1 and 1′ in the first example can be reduced up to 25 mV.

FIG. 7 shows a relation between the relative substrate concentration indicative of a concentration ratio of a substrate when the concentration of the semiconductor substrate 10 is normalized based on the concentration of the semiconductor substrate 110 and the variation in the threshold voltages Vth (Vth variation) of the memory cell transistor. The variation σ in the threshold voltages Vth on the vertical axis depends on the processing variation of the gate electrode, the dopant impurity concentration distribution and the gate oxide film thickness. The variation a in the threshold voltages Vth is approximately proportional to the relative substrate concentration as shown in FIG. 7. For this reason, by setting the concentration of the semiconductor substrate 10 to be lower than the concentration of the semiconductor substrate 110 by 10%, the variation a in the threshold voltages Vth in the memory cell transistor of the first example can be made lower than the variation σ in the threshold voltages Vth in the conventional memory cell transistor by 5 mV. As a result, in the conventional memory cell transistor, the variation σ in the threshold voltages Vth caused by the processing variation of the gate electrodes 101 and 101′, the dopant impurity concentration distribution and the gate oxide film thickness is 90 mV as a whole. However, in the memory cell transistor of the first example, the variation σ in the threshold voltages Vth caused by the processing variation of the gate electrodes 1 and 1′, the dopant impurity concentration distribution and the gate oxide film thickness can be reduced to 60 mV as a whole.

In this way, for the write guarantee of 75% and protection of the data destruction caused by the channel leak, it could be understood that the variation σ in the threshold voltages Vth needs to be equal to or less than 70 mV as a whole and the gate length needs to be 1.3 F or more in order to attain this.

The memory cell transistor of the first example is designed so as to set the gate lengths of the gate electrodes 1 and 1′ to 1.3 F. Thus, the variation σ in the threshold voltages Vth can be reduced to 60 mV as a whole (the reduction of 30 mV from the variation σ in the threshold voltages Vth of the conventional memory cell transistor). Moreover, the concentration of the semiconductor substrate 10 to adjust the threshold voltage Vth can be 10% lower than the concentration of the semiconductor substrate 110 in the conventional memory cell transistor.

Thus, since the memory cell transistor of the first embodiment is designed so as to set the gate lengths of the gate electrodes 1 and 1′ to 1.3 F, the junction electric field in the interfaces between the semiconductor substrate 10 and the diffusion layers 11, 11′ and 12 can be reduced less than the junction electric field in the interfaces between the semiconductor substrate 110 and the diffusion layers 111, 111′ and 112 in the conventional memory cell transistor.

Since the memory cell transistor of the first example is designed so as to reduce the junction electric field in the interfaces between the semiconductor substrate 10 and the diffusion layers 11, 11′ and 12, the junction leak current flowing through the interfaces between the semiconductor substrate 10 and the diffusion layers 11, 11′ and 12 can be reduced less than the junction leak current flowing into the boundaries between the semiconductor substrate 110 and the diffusion layers 111, 111′ and 112 in the conventional memory cell transistor.

Since the memory cell transistor of the first example is designed so as to reduce this junction leak current, the data holding time can be made longer than the data holding time of the conventional memory cell transistor, thereby improving the data holding performance.

Therefore, since the memory cell transistor of the first example is designed so as to make the data holding time longer, the electric power (electric power consumption) used in the charging and discharging operations when the data are written into the cell capacitive sections 6 and 6′ and when the data are read out from the cell capacitive sections 6 and 6′ can be reduced less than in the conventional memory cell transistor.

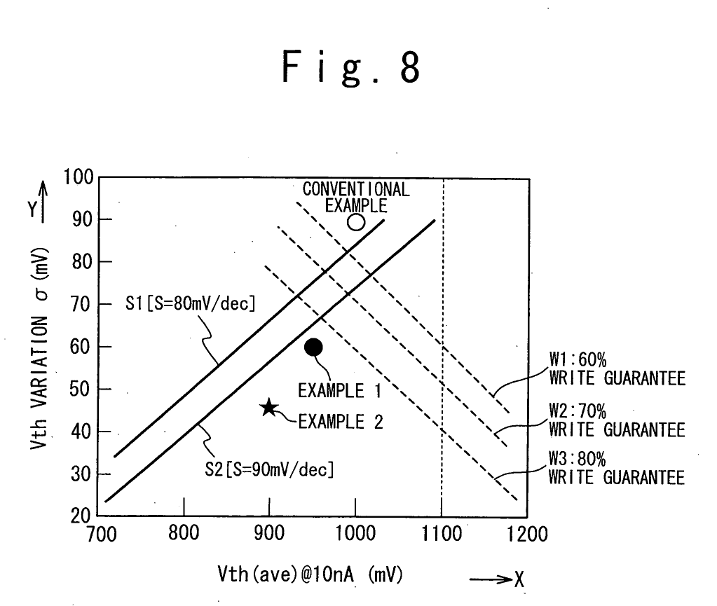

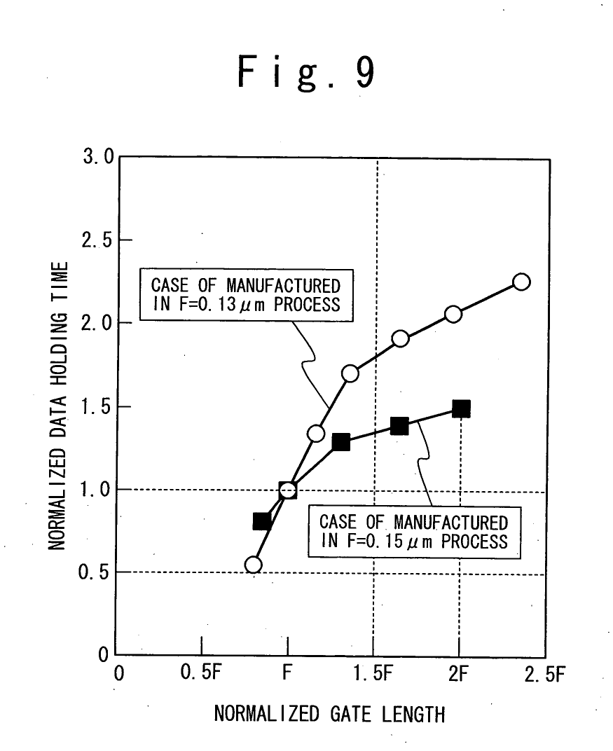

As the effect of the memory cell transistor of the first example, the improvement of the data holding performance will be described below in detail with reference to FIGS. 8 and 9.

In case of the 256 Mbit DRAM, the data shown in FIG. 8 are required as the threshold voltages Vth and the variations of them for the memory cell transistor. FIG. 8 shows a relation between the averages of the threshold voltages Vth of the memory cell transistors in the conventional technique and the present invention and the variations of the threshold voltages Vth (the Vth variations) of the memory cell transistors in the conventional technique and the present invention. The horizontal axis Y of FIG. 8 indicates the averages of the threshold voltages Vth in the memory cell transistor, and the vertical axis Y of FIG. 8 indicates the variations σ in the threshold voltages Vth (the Vth variations) in the memory cell transistor. The variation σ in the threshold voltages Vth on the vertical axis Y depends on the processing variation of the gate electrode, the dopant impurity concentration distribution and the gate oxide film thickness.

Referring to FIG. 8, threshold lines S1, S2 are lines when data destruction is induced by channel leak at a high temperature of about 85° C., in the transistor of the minimum threshold voltage Vth in the 256 Mbits, when a sub threshold coefficient S is given. The threshold line S1 is the threshold line when the sub threshold coefficient S is 80 mV/dec, and it is represented by a function Y1=a*X+b1 (a and b1 are constants). The plane coordinate indicated by the horizontal axis (the variation in the threshold voltages Vth) X and the vertical axis (the average of the threshold voltages Vth) Y is partitioned off into a first region equal to or greater than the function value Y1 represented by the threshold line S1 and a second region less than the function value Y1 represented by the threshold line S1, by the threshold line S1. The threshold line S2 is the threshold line when the sub threshold coefficient S is 90 mV/dec, and it is represented by a function Y2=a*X+b2 (a and b2 are constants). The plane coordinate indicated by the horizontal axis X and the vertical axis Y is partitioned off into a first region equal to or greater than the function value Y2 represented by the threshold line S2 and a second region less than the function value Y2 represented by the threshold line S2, by the threshold line S2. In case of the second region partitioned off by the threshold lines S1 and S2, the data destruction is not induced by the channel leak. In case of the first region partitioned off by the threshold lines S1 and S2, the data destruction is induced by the channel leak.

Also, FIG. 8 shows threshold lines W1, W2 and W3 where a write defect is induced in the transistor of the maximum threshold voltage Vth in the 256 Mbits, when a write rate as a rate of a writing operation guarantee of required data is given.

The threshold line W1 is the threshold line for the writing operation guarantee of 60% as the write rate, and it is represented by a function Y11=−c*X+d11 (c and d11 are constants). The plane coordinate indicated by the horizontal axis X and the vertical axis Y is partitioned off into a first region equal to or greater than the function value Y11 represented by the threshold line W1 and a second region less than the function value Y11 represented by the threshold line W1. The threshold line W2 is the threshold line for the writing operation guarantee of 70% as the write rate, and it is represented by a function Y12=−c*X+d12 (c and d12 are constants). The plane coordinate indicated by the horizontal axis X and the vertical axis Y is partitioned off into a first region equal to or greater than the function value Y12 represented by the threshold line W2 and a second region less than the function Y12 represented by the threshold line W2. The threshold line W3 is the threshold line the writing operation guarantee of 80% as the write rate, and it is represented by a function Y13=−c*X+d13 (c and d13 are constants). The plane coordinate indicated by the horizontal axis X and the vertical axis Y is partitioned off into a first region equal to or greater than the function value Y13 represented by the threshold line W3 and a second region less than the function value Y13 represented by the threshold line W3.

In case of the second region partitioned off by the threshold lines W1, W2 and W3, the write defect is not induced. In case of the first region partitioned off by the threshold lines W1, W2 and W3, the write defect is induced. In the first example, the variation σ in the threshold voltages Vth can be reduced to 60 mV. Thus, as indicated by a black circular mark, the average of the threshold voltages Vth can be set to 0.95 V. For this reason, the variation σ in the threshold voltages Vth and the average of the threshold voltages Vth belong to the second region partitioned off by the threshold lines S1 and S2, and simultaneously belong to the second region partitioned off by the threshold line W3. Therefore, in the memory cell transistor of the first example, the margin can be guaranteed for the data destruction caused by the channel leak and the write defect, thereby insuring the writing of 80% or more.

FIG. 9 shows a relation between a normalized gate length and a normalized data holding time. The normalized gate length on the horizontal axis of FIG. 9 is the gate length of the gate electrode that is normalized on the basis of F indicative of the gate lengths of the gate electrodes 101 and 101′ in the conventional memory cell transistor. That is, when F is 0.13 μm, the normalized gate length 1 F becomes 0.13 μm, and the normalized gate length becomes 0.26 μm in case of 2 F. The normalized data holding time on the vertical axis of FIG. 6 is the data holding time normalized on the basis of the data holding time when the gate length is F (the data holding time of the conventional memory cell transistor). It is supposed that the normalized data holding time is 1 when the gate length is F (F=0.13 μm). In this case, the normalized data holding time is 2 when the gate length is 2 F (2 F=0.26 μm)) Actually, if the data holding time is assumed to be 200 ms when the gate length is F, the data holding time becomes 400 ms when the gate length is 2 F.

As mentioned above, as the result that the margin can be guaranteed from the data destruction caused by the channel leak and the write defect, as shown in FIG. 9, although the conventional memory cell transistor having the gate length of F has the data holding time of 200 ms, the memory cell transistor having the gate length of 1.3 F in the first example achieves the improvement that the data holding time is 340 ms equal to 1.7 times that of the conventional case.

The gate length dependence of the data holding time as mentioned above is found out from the study of the inventor that there is the different dependence between the case below 1.3 F and the case of 1.3 F or more, even if the DRAM is manufactured in the process having the different F value. If the gate length is less than 1.3 F, the data holding time is short similarly to the conventional memory cell transistor, and the data holding time is largely varied depending on the dimensional variation (processing variation) in the gate length. Thus, it is difficult to obtain the stable data holding performance. Usually, the variation in the data holding time has influence on a yield drop in the product. On the other hand, if the gate length is 1.3 F or more (in the case of the present invention), the data holding time is longer than that of the case in which the gate length is less than 1.3 F, and even if there is the dimensional variation in the gate length, the variation in the data holding time can be reduced, thereby obtaining the stable data holding performance. According to the present invention, it is possible to improve the data holding performance and keep the yield of the product stable.

Also, as shown in FIG. 9, it could be understood that the effect increases in the future advancement of the miniature structure by setting the gate length to be equal to or longer than 1.3 F. If the gate length is set to 1.3 F when the half pitch F is 0.15 μm in the memory cell transistor of the present invention, the data holding time of the memory cell transistor of the present invention becomes 1.3 times the data holding time of the conventional memory cell transistor. However, if the gate length is set to 1.3 F when the half pitch F is 0.13 μm in the memory cell transistor of the present invention, the data holding time of the memory cell transistor of the present invention can be 1.7 times the data holding time of the conventional memory cell transistor. That is, if the F value is made smaller, the data holding time can be effectively made longer. In this way, according to the present invention, as the miniature structure is advanced, the degree of the performance improvement becomes greater.

As the effect of the memory cell transistor in the first example, the high speed operation of the memory cell transistor will be described below in detail. It should be noted that in the memory cell transistor of the first example, the areas of the cell capacitive sections 6 and 6′ are increased by 13% in correspondence to the increase in the area per cell, as compared with the cell capacitive sections 106 and 106′ of the conventional memory cell transistor. In the memory cell transistor of the first example, since the gate lengths of the gate electrodes 1 and 1′ are widened to 1.3 F, resistances of the gate electrodes 1 and 1′ can be reduced by 20% as compared with resistances of the gate electrodes 101 and 101′. The memory cell transistor of the first example is operated at a speed higher than that of the conventional memory cell transistor, because the resistances of the gate electrodes 1 and 1′ are reduced by 20% as compared with the resistances of the gate electrodes 101 and 101′.

From the above-mentioned explanation, according to the memory cell transistor of the first example, the data holding time can be made longer than the data holding time of the conventional memory cell transistor. Thus, the data holding time is improved.

According to the memory cell transistor of the first example, since the data holding time is made longer, the electric power consumption can be reduced over the electric power consumption of the conventional memory cell transistor.

According to the memory cell transistor of the first example, it is operated at the speed higher than that of the conventional memory cell transistor.

(Second Example)

As the layout of the memory cell transistor in the second embodiment, the gate lengths of the gate electrodes 1 and 1′ are 2 times the half pitch F, namely, 2 F that is 2 times the gate lengths F of the gate electrodes 101 and 101′ of the conventional memory cell transistor. The half pitch F that is the minimum processing dimension shown in FIG. 4 is assumed to be 0.13 μm. When the resist dimensions before the gate electrodes 1 and 1′ are processed are assumed to be 0.145 μm, the contraction is carried out for the side etching when the gate electrodes 1 and 1′ are processed. After the gate electrodes 1 and 1′ are processed, the thermal oxidization is performed on the side walls of the gate electrodes 1 and 1′. As a result, the effective gate lengths of the gate electrodes 1 and 1′ in this second embodiment are 0.27 μm.

As another layout of the memory cell transistor in the second example, the following is accomplished.

At first, the gate interval between the gate electrode 1 and the gate electrode 1′ is defined as F in order to protect the area from being unnecessarily increased. The side or diameter of the capacitive contact sections 4 and 4′ are also defined as F in order to protect the area from being unnecessarily increased. The side or diameter of the bit line contact section 5 is also defined as F in order to protect the area from being unnecessarily increased.

As for the transistor region 2, since the gate lengths of the gate electrodes 1, 1′ are 2 times longer than the gate lengths of the gate electrodes 101 and 101′ of the conventional memory cell transistor, respectively, it is longer in a longitudinal direction than the transistor region 102 of the conventional memory cell transistor. That is, the shortest distance between the diffusion layer 11 and the diffusion layer 12 is proportional to the gate length of the gate electrode 1 and 2 times longer than the shortest distance between the diffusion layer 111 and the diffusion layer 112 in the conventional memory cell transistor. The shortest distance between the diffusion layer 11′ and the diffusion layer 12 is proportional to the gate length of the gate electrode 1′ and 2 times longer than the shortest distance between the diffusion layer 111′ and the diffusion layer 112 in the conventional memory cell transistor.

In this way, in the memory cell transistor in the second example, the area per cell is increased. In the memory cell transistor in the second example, the areas of the cell capacitive sections 6 and 6′ can be increased more in correspondence to this increase in the area than those of the cell capacitive sections 106 and 106′ of the conventional memory cell transistor.

The memory cell transistor in the second example will be described below in detail with reference to FIGS. 6 and 7. As shown in FIG. 6, in the conventional memory cell transistor, the impurity concentration of the substrate concentration 110 used in the semiconductor substrate 110 is assumed to be 1 when the gate electrodes 101 and 101′ whose gate lengths are F are used to adjust the threshold voltage Vth to 1 V. In the memory cell transistor of the second example, the substrate concentration used in the semiconductor substrate 10 is 0.75 when the gate electrodes 1 and 1′ whose gate lengths are 2 F are used to adjust the threshold voltage Vth to 1 V. That is, the concentration of the semiconductor substrate 10 is 25% lower than the concentration of the semiconductor substrate 110. For this reason, it is supposed that the dimensional variation (processing variation) when the gate electrodes 1 and 1′ in the second example are processed is 4 nm equal to the processing variation of the conventional gate electrodes 101 and 101′. Then, the variation a in the threshold voltages Vth caused by the processing variation of the conventional gate electrodes 101 and 101′ is 50 mV. However, the variation a in the threshold voltages Vth caused by the processing variation of the gate electrodes 1 and 1′ in the second example can be reduced up to 15 mV.

As shown in FIG. 7, the variation a in the threshold voltages Vth is approximately proportional to the relative substrate concentration. Thus, by setting the concentration of the semiconductor substrate 10 to be 25% lower than the concentration of the semiconductor substrate 110, the variation σ in the threshold voltages Vth in the memory cell transistor of the second example can be made lower than the variation σ in the threshold voltages Vth in the conventional memory cell transistor by 12 mV. As a result, in the conventional memory cell transistor, the variation σ in the threshold voltages Vth caused by the processing variation of the gate electrodes 101 and 101′, the dopant impurity concentration distribution and the gate oxide film thickness is 90 mV as a whole. However, in the memory cell transistor of the second example, the variation σ in the threshold voltages Vth caused by the processing variation of the gate electrodes 1 and 1′, the dopant impurity concentration distribution and the gate oxide film thickness can be reduced to 45 mV as a whole.

In this way, the memory cell transistor of the second example is designed so as to set the gate lengths of the gate electrodes 1 and 1′ to 2 F. Thus, the variation σ in the threshold voltages Vth can be reduced to 45 mV as a whole (the reduction of 45 mV from the variation σ in the threshold voltages Vth of the conventional memory cell transistor). Moreover, the concentration of the semiconductor substrate 10 to adjust the threshold voltage Vth can be 25% lower than the concentration of the semiconductor substrate 110 in the conventional memory cell transistor.

Thus, since the memory cell transistor of the second example is designed so as to set the gate lengths of the gate electrodes 1 and 1′ to 2 F, the junction electric field in the interfaces between the semiconductor substrate 10 and the diffusion layers 11, 11′ and 12 can be reduced more than the junction electric field on the boundaries between the semiconductor substrate 110 and the diffusion layers 111, 111′ and 112 in the conventional memory cell transistor.

Since the memory cell transistor of the second example is designed so as to reduce the junction electric field in the interfaces between the semiconductor substrate 10 and the diffusion layers 11, 11′ and 12, the junction leak current flowing through the interfaces between the semiconductor substrate 10 and the diffusion layers 11 and 11′ and 12 can be reduced more than the junction leak current flowing into the boundaries between the semiconductor substrate 110 and the diffusion layers 111, 111′ and 112 in the conventional memory cell transistor.

Since the memory cell transistor of the second example is designed so as to reduce this junction leak current, the data holding time can be made longer than the data holding time of the conventional memory cell transistor. Thus, the data holding performance is improved in the memory cell transistor of the second example.

For this reason, since the memory cell transistor of the second example is designed so as to make the data holding time longer, the electric power consumption in the charging and discharging operations when the data are written to the cell capacitive sections 6 and 6′ and when the data are read out from the cell capacitive sections 6 and 6′ can be reduced over that in the conventional memory cell transistor. As the effect of the memory cell transistor of the second example, the improvement of the data holding performance will be described below in detail with reference to the review results (FIGS. 8 and 9).

In the case of the 256 Mbit DRAM, the threshold voltages Vth and the variations thereof required for the memory cell transistor are shown in FIG. 8. In the second example, the variation σ in the threshold voltages Vth can be reduced to 45 mV. Thus, as indicated by a star mark, the average of the threshold voltages Vth can be set to 0.9 V. For this reason, the variation σ in the threshold voltages Vth and the average of the threshold voltages Vth belong to the second region partitioned off by the threshold lines S1 and S2, and simultaneously belong to the second region partitioned off by the threshold line W3. Therefore, in the memory cell transistor of the second example, the margin can be reserved for the data destruction caused by the channel leak and the write defect, thereby insuring the writing of 80% or more.

As mentioned above, as the result that the margin can be guaranteed for the data destruction caused by the channel leak and the write defect, as shown in FIG. 9, although the conventional memory cell transistor having the gate length of F has the data holding time of 200 ms, the memory cell transistor having the gate length of 2 F in the second example achieves the improvement that the data holding time is 340 ms equal to 1.7 times that of the conventional case.

As the effect of the memory cell transistor in the second example, the high speed operation of the memory cell transistor will be described below in detail. By the way, in the memory cell transistor of the second example, the areas of the cell capacitive sections 6 and 6′ are increased by 36% in correspondence to the increase in the area per cell, as compared with the cell capacitive sections 106, 106′ of the conventional memory cell transistor. In the memory cell transistor of the second example, since the gate lengths of the gate electrodes 1 and 1′ are widened to 2 F, the resistances of the gate electrodes 1 and 1′ can be reduced by 50% as compared with the resistances of the gate electrodes 101 and 101′. Therefore, the memory cell transistor of the second example is operated at the speed higher than that of the conventional memory cell transistor, because the resistances of the gate electrodes 1 and 1′ are reduced by 50% as compared with the resistances of the gate electrodes 101 and 101′ in the conventional memory cell transistor.

From the above-mentioned explanation, according to the memory cell transistor of the second example, the data holding time can be made longer than the data holding time of the conventional memory cell transistor and the data holding time of the memory cell transistor in the first example. Thus, the data holding time is improved.

According to the memory cell transistor of the second example, since the data holding time is made longer, the electric power consumption can be reduced over the electric power consumption of the conventional memory cell transistor and the electric power consumption of the memory cell transistor in the first example.

According to the memory cell transistor of the second example, it is operated at the speed higher than those of the conventional memory cell transistor and the memory cell transistor in the first example.

In the semiconductor memory device of the present invention, the data holding performance is improved by making the data holding time longer. Also, in the semiconductor memory device of the present invention, the electric power consumption is reduced. Also, the semiconductor memory device of the present invention is operated at the high speed.

1. A semiconductor memory device, comprising:
a semiconductor substrate; and
gate electrodes formed for a transistor on said semiconductor substrate through a gate insulating film,
wherein a gate length of said gate electrode is longer than a minimum processing dimension.

2. The semiconductor memory device according to claim 1, further comprising:
a first diffusion layer formed in a surface of said semiconductor substrate to function as one of a source and a drain; and
a second diffusion layer formed in the surface of said semiconductor substrate to function as the other of said source and said drain,
wherein the shortest distance between said first diffusion layer and said second diffusion layer is proportional to said gate length.

3. The semiconductor memory device according to claim 2, further comprising:
a gate insulating film formed on said semiconductor substrate and extending over said first diffusion layer and said second diffusion layer,
wherein said gate electrode is formed on said gate insulating film.

4. The semiconductor memory device according to claim 2, further comprising:
a first insulating film provided to cover said gate electrode;
a first contact section formed to pass through said first insulating film to said first diffusion layer;
a bit line formed on said insulating film;
a second contact section formed to pass through said insulating film to said second diffusion layer; and
a capacitive section formed on said first insulating film and connected to said first contact section.

5. The semiconductor memory device according to claim 4, wherein a side length or diameter of said first contact section is said minimum processing dimension; and
a side length or diameter said second contact section t is said minimum processing dimension.

6. The semiconductor memory device according to claim 5, further comprising:
a second insulating film formed to cover said first insulating film, said first contact section, said second contact section and said bit line;
wherein said capacitive section is formed on said second insulating film, and said capacitive section comprises a lower electrode, a capacitive insulating film formed on said lower electrode and an upper electrode formed on said capacitive insulating film; and
a third contact section formed to pass through said second insulating film to said first contact section.

7. The semiconductor memory device according to claim 1, wherein an impurity concentration of said semiconductor substrate is lower than an impurity concentration of said semiconductor substrate when the gate length of said gate electrode is said minimum processing dimension.

8. The semiconductor memory device according to claim 1, wherein the gate length of said gate electrode is equal to or longer than 1.3 times said minimum processing dimension.

9. A semiconductor memory device, comprising:
a first MOS transistor formed on a first surface of a semiconductor substrate; and
a second MOS transistor formed on a second surface of said semiconductor substrate,
wherein said first MOS transistor has a first gate electrode,
said second MOS transistor has a second gate electrode, and
a gate length of said first gate electrode and a gate length of said second gate electrode are longer than a minimum processing dimension.

10. The semiconductor memory device according to claim 9, wherein said first MOS transistor further comprises a first diffusion layer functioning as one of a source and a drain and a second diffusion layer functioning as the other of said source and said drain,
said second MOS transistor further comprises a third diffusion layer functioning as one of said source and said drain and said second diffusion layer functioning as the other of said source and said drain,
said second diffusion layer is used in common to said first MOS transistor and said second MOS transistor,
the shortest distance between said first diffusion layer and said second diffusion layer is proportional to the gate length of said first gate electrode, and
the shortest distance between said third diffusion layer and said second diffusion layer is proportional to the gate length of said second gate electrode.

11. The semiconductor memory device according to claim 10, wherein said first MOS transistor further comprises a first gate insulating film extending over said first diffusion layer and said second diffusion layer,
said second MOS transistor further comprises a second gate insulating film extending over said third diffusion layer and said second diffusion layer,
said first gate electrode is formed on said first gate insulating film, and
said second gate electrode is formed on said first gate insulating film.

12. The semiconductor memory device according to claim 10, further comprising:
a first insulating film formed to cover said first gate electrode and said second gate electrode;
a first contact section formed to pass through said first insulating film to said first diffusion layer;
a bit line formed on said first insulating film;
a second contact section formed to pass through said first insulating film to said second diffusion layer;
a third contact section formed to pass through said first insulating film to said third diffusion layer;
a first capacitive section formed on said first insulating film and connected to said first contact section; and
a second capacitive section formed on said first insulating film and connected to said third contact section.

13. The semiconductor memory device according to claim 12, wherein a side length or diameter of said first contact section is said minimum processing dimension,
a side length or diameter of said second contact section is said minimum processing dimension, and
a side length or diameter of said third contact section is said minimum processing dimension.

14. The semiconductor memory device according to claim 13, further comprising:
a second insulating film formed to cover said first insulating film, said first contact section, said second contact section, said third contact section and said bit line;
wherein said first capacitive section and said second capacitive section are formed on said second insulating film, and each of said first capacitive section and said second capacitive section has a lower electrode, a capacitive insulating film formed on said lower electrode and an upper electrode formed on said capacitive insulating film; and
a fourth contact section formed to pass through said second insulating film to said first contact section; and
a fifth contact section formed to pass through said second insulating film to said third contact section.

15. The semiconductor memory device according to claim 9, wherein a gate interval between said first gate electrode and said second gate electrode is said minimum processing dimension.

16. The semiconductor memory device according to claim 9, wherein an impurity concentration of said semiconductor substrate is lower than an impurity concentration of said semiconductor substrate when the gate length of said first gate electrode and the gate length of said second gate electrode are said minimum processing dimension.

17. The semiconductor memory device according to claim 9, wherein the gate length of said first gate electrode and the gate length of said second gate electrode are equal to or longer than 1.3 times said minimum processing dimension.
